(19) United States
(12) Patent Application Publication
(10) Pub. No.: US 2013/0119117 A1
(43) Pub. Date: May 16, 2013

(54) BONDING WEDGE

(71) Applicant: Invensas Corporation, San Jose, CA (US)

(72) Inventor: Scott McGrath, Scotts Valley, CA (US)

(73) Assignee: Invensas Corporation, San Jose, CA (US)

(21) Appl. No.: 13/667,289

(22) Filed: Nov. 2, 2012

Related U.S. Application Data
(60) Provisional application No. 61/556,141, filed on Nov. 4, 2011.

(51) Int. Cl. H01L 23/00

(52) U.S. Cl. CPC H01L 24/43
USPC 228/160; 228/4.5; 228/180.5

(57) ABSTRACT

A bonding wedge particularly suitable for making wire off-die interconnects includes an aperture opening onto a notch or pocket adjacent to the rear of a foot. The foot includes a heel portion and a toe portion. When the bonding wedge is in use, a wire is fed from feedstock through the aperture and the notch or pocket, and passes beneath the foot and extends beyond the toe. The toe is configured to mitigate upward displacement of the free end of the wire during the bonding process.

### CROSS-REFERENCE TO RELATED APPLICATION

This application claims the benefit of the filing date of U.S. Provisional Application No. 61/556,141 filed Nov. 4, 2011, the disclosure of which is incorporated herein by reference.

### BACKGROUND OF THE INVENTION

This disclosure relates to a wire bonding wedge and, particularly, to a bonding wedge for making wire off-die interconnects.

A typical semiconductor die has a front (“active”) side, in which the integrated circuitry is formed, a back side, and sidewalls. The sidewalls meet the front side at front edges and the back side at back edges. Semiconductor die typically are provided with interconnect pads (die pads) located at the front side for electrical interconnection of the circuitry on the die with other circuitry in the device in which the die is deployed. Some die as provided have die pads on the front side along one or more of the die margins, and these may be referred to as peripheral pad die. Other die as provided have die pads arranged in one or two rows at the front side near the center of the die, and these may be referred to as central pad die. The die may be “rerouted” to provide a suitable arrangement of interconnect pads at or near one or more of the margins of the die.

Semiconductor die may be electrically connected with other circuitry, for example in a printed circuit board, a package substrate or lead frame, or another die, by any of several kinds of interconnects. Connection may be made by, for example, wire bonds, or flip chip interconnects, or tab interconnects.

In ball-to-stitch wire bond interconnect, fine wires are use to make electrical connections between contact sites, which may be, for example, an interconnect pad on a die and a bond finger on a lead frame or a bond site on a substrate. The wire is fed through a capillary wire bond tool. The tool is used to form a bond at the first contact site, to draw the wire from the first contact site to the second contact site, and to form a bond at the second contact site. Typically, a ball is formed at the free end of the wire and the ball is bonded to a first contact site by application of force and heat and ultrasound energy. Then the wire is fed through the tool and the tool is moved to a second contact site, forming a loop in the wire, and the wire is stitch bonded (wedge bonded) at the second site, again by application of force and heat and ultrasound energy, to complete the interconnection. The wire is then broken at the end of the wedge bond, forming a new free end on which a ball can be formed to repeat the process to form interconnections between another pair of contact sites.

In stitch-to-stitch wire bond interconnect, a bonding wedge is used to stitch bond (wedge bond) the free end of the wire to the first contact site; then the wire is fed through the wedge and the wedge is moved to the second contact site; and the wedge is used to stitch bond the wire at the second site.

A number of approaches have been proposed for increasing the density of active semiconductor circuitry in integrated circuit chip packages, while minimizing package size (package footprint, package thickness). In one approach to making a high density package having a smaller footprint, two or more semiconductor die of the same or different functionality are stacked one over another and mounted on a package substrate. Electrical interconnection of stacked semiconductor die presents a number of challenges. A variety of stacked die configurations has been proposed and the various arrangements of die in the stack may be designed at least in part to meet these challenges.

Die may be interconnected by forming durable contact of interconnects with selected corresponding pads on the respective die. Alternatively, the die pads may be provided with interconnect terminals, and the die may be interconnected by forming durable contact of interconnect traces with selected corresponding interconnect terminals on the respective die. An interconnect terminal may include, for example, a tab bond or ribbon bond, and may extend from the pad beyond the die edge (so-called “off-die” terminal).

U.S. Pat. No. 7,215,018 and U.S. Pat. No. 7,245,021 describe vertical electrical interconnection of stacked die by applying electrically conductive polymer, or epoxy, filaments or lines to sides of the stack. In the illustrated configurations, the die are stacked so that their interconnect edges are substantially aligned vertically over one another, so that the stack presents an interconnect stack face that is generally planar and is oriented generally perpendicularly to the substrate surface. Also, in the illustrated configurations, the corresponding interconnect terminals on the respective die are vertically aligned one over another arranged with respect to the substrate surface. Accordingly, the electrically conductive interconnect filaments or lines are oriented substantially normal to the substrate surface, and the off-die terminals project into the interconnect filaments.

Wire bond off die terminals may be formed using a wedge bonding tool. The wire is first fed through an aperture in the tool and under the bonding foot, and extending the free end of the wire to form an elongated tail. Then the tool is moved toward the bond pad, so that the foot presses the wire onto the pad, and heat and ultrasound energy are applied to form the bond. Then the tool is moved away from the stitch bond and the wire is snapped off near the stitch bond to form a new free end with an elongated tail. The process is then repeated at another bond pad.

In any particular arrangement of pads on the die, the pads may not be suitably vertically aligned with bond sites on the underlying support. They may, for example, be misaligned to some extent as a result of the circuit designs. Or, for example, it may be desirable for a pad on a die to be interconnected with a bond site on the underlying support that is vertically aligned with an adjacent die pad (that is, in effect rerouting the connection). In such instances, it may be necessary to employ wire bond off-die terminals each including a wire stitched to the die pad and extending to and beyond an interconnect die edge, in which where necessary the wire is directed at an angle non-perpendicular to the interconnect die edge.

Where the angle in the extended wire corrects for a misalignment, the angle may be in the range of a few degrees away from perpendicular to the die edge; where the angle in the extended wire provides for rerouting the connection, the angle may be in a range as large as about ±50° from perpendicular or greater.

The angle of the extended wire is established by rotating the wedge bonding tool about a vertical axis so that the extended tail projects at an appropriate angle prior to forming the bond. Where the first connection site (e.g., the die pad) and the second connection site (e.g., a bond pad on an underlying support) are well-aligned, the tool is rotated so that the extended wire is substantially perpendicular to the interconnect die edge. Where the first and second connection sites are misaligned or where rerouting of the connection is required, the tool is rotated so that the free end of the extended wire is substantially vertically aligned over the second connection site.

### SUMMARY OF THE INVENTION

In processes for forming wire off-die interconnects using wedge bond technology, we have observed that the elongated tail may be displaced at an angle upward during the application of bond force and heat and ultrasound energy. Where the connection is made through a narrow opening through a passivation layer, the upward displacement may be worsened. It is preferable for the wires to extend nearly in a plane generally parallel to the active side of the die, and so the upwardly angled tails are not acceptable. Following formation of the off-die interconnects the tails may be flattened by pressing a flat surface downward onto the free ends; but we have found that this can result in changes in the desired angles of the leads with respect to the interconnect die edge.

Accordingly, embodiments of the invention in one general aspect feature a bonding wedge that includes an aperture opening onto a notch or pocket adjacent and to the rear of a foot. The foot includes a heel portion and a toe portion. When the bonding wedge is in use a wire is fed from feedstock through the aperture and the notch or pocket, and passes beneath the foot and extends beyond the toe. The toe is configured to confine the extended tail and thereby to mitigate upward displacement of the free end of the wire during the bonding process.

A wedge-bonding tool according to an aspect of the invention can include a wedge body having a foot configured to apply a downward force on a wire during the bonding of the wire to a contact pad of a component exposed at a major surface of the component. The foot can include a toe and a heel, wherein a front side of the toe may be displaced from a front side of the heel in a lateral direction parallel to the major surface and an underside of the toe can be displaced from an underside of the heel in an upward direction away from the major surface. The heel can be configured to apply the force at a first location of the wire proximate the contact pad to bond the wire to the contact pad. The toe can be configured to simultaneously contact a tail of the wire at a second location of the wire in a state in which the heel is applying the force, so as to set a height of the wire above the component major surface at the second location.

In one or more examples, the toe may have a lower surface having a concavity therein which is configured to guide the tail of the wire during the bonding of the wire to the contact pad.

In one or more examples, the depth of the concavity can be less than a diameter of the wire defined by an outer surface of the wire. The concavity can be in form of a channel extending in the lateral direction from the front side of the toe towards the heel.

In one or more examples, the component can be a semiconductor die. In one or more examples, in a state in which the wire has been bonded to the contact pad, the wedge body can be configured such to affect a tail of the wire having a free end to have an elevation L in a direction perpendicular to a plane defined by the major surface, such that the length S of the tail of the wire between the free end and the first location of the wire defines an angle between the tail and the major surface, the angle being less than 45 degrees.

In one or more examples, the angle can be less than 30 degrees.

In one or more examples, the component has a peripheral edge extending away from the major surface and the wedge-bonding tool can be configured to leave the free end of the wire disposed beyond the peripheral edge.

In one or more examples, the wedge body can be configured to sever the wire at a location proximate the contact pad.

In one or more examples, the toe can have a flat surface extending in the lateral direction between the front side of the heel and the front side of the toe.

In one or more examples, the underside of the toe at the front side thereof can be displaced upwardly from the underside of the heel at the front side of the heel by a distance of at least a diameter of an outer surface of the wire.

In one or more examples, the component can include a plurality of contact pads and the contact pads can be exposed within at least one opening in a dielectric layer having a surface defining the major surface of the component. The underside of the toe at the front side thereof may be displaced upwardly from the underside of the heel at the front side of the heel by a distance of at least a diameter of an outer surface of the wire and a distance in the upward direction from the exposed contact pad to the major surface of the component.

In one or more examples, the front side of the toe may be displaced in the lateral direction from the front side of the heel by a distance greater than twice the diameter of the wire.

A wedge-bonding method in accordance with another aspect of the invention may include positioning a wedge body having a wire extending therefrom proximate a contact pad exposed at a major surface of a component. The wedge body can be moved downwardly such that a heel of the wedge body applies a force on the wire at a first location of the wire proximate the contact pad to bond the wire to the contact pad, and such that an underside of a toe of the wedge body which is laterally and upwardly displaced from the heel contacts a tail of the wire at a second location of the wire at a time when the heel applies the force. In such way, the toe can set a height of the wire above the component major surface at the second location.

In one or more examples, the toe may have a lower surface having a concavity therein, wherein the concavity guides the tail of the wire. In one or more examples, the concavity can be in form of a channel extending from the front side of the toe towards the heel. In one or more examples, the concavity may be in form of an angled trough.

In one or more examples, the depth of the concavity can be less than a diameter of the wire defined by an outer surface of the wire.

In one or more examples, the component can be a semiconductor die. In one or more examples, the tail of the wire has a free end, and the moving can be performed such that an elevation L of the free end in a direction perpendicular to a plane defined by the major surface, and the length S of the wire between the free end and the first location of the wire defines an angle between the tail of the wire and the major surface, the angle being less than 45 degrees.

In one or more examples, the angle can be less than 30 degrees.

In one or more examples, the component has a peripheral edge extending away from the major surface and the moving of the wedge body can be performed so as to form the wire having the free end extending beyond the peripheral edge.

In one or more examples, the method may further include severing the wire at a location proximate the contact pad.

In one or more examples, the toe may have a flat surface extending in the lateral direction between the front side of the heel and the front side of the toe. The method may further include contacting the wire with at least a portion of the flat surface.

In one or more examples, the underside of the toe at the front side thereof can be displaced upwardly from the underside of the heel at the front side of the heel by a distance of at least a diameter of an outer surface of the wire.

In one or more examples, the contact pads can be exposed within at least one opening in a dielectric layer having a surface defining the major surface of the component. The underside of the toe at the front side thereof can be displaced upwardly from the underside of the heel at the front side of the heel by a distance of at least a diameter of an outer surface of the wire and a distance in the upward direction from the exposed contact pad to the major surface of the component.

In one or more examples, the front side of the toe may be displaced in the lateral direction from the front side of the heel by a distance greater than twice the diameter of the wire.

### BRIEF DESCRIPTION OF THE DRAWINGS

FIGS. 1A and 1B are diagrammatic sketches in a sectional view showing a bonding wedge known in the art, being deployed to form a wedge bond at a first bond site.

FIG. 1C is a diagrammatic sketch showing a completed wedge bond at a first bond site, formed as shown in FIGS. 1A and 1B.

FIG. 2A is a diagrammatic sketch in a sectional view showing a die having a stitched wire off-die terminal, mounted onto a substrate.

FIG. 2B is a diagrammatic sketch in plan view showing a die having stitched wire off-die terminals projecting at various angles with respect to the interconnect die edge, mounted onto a substrate.

FIGS. 3A, 3B are diagrammatic sketches in sectional view showing formation of a stitched wire off-die terminal using a bonding wedge of the type shown in FIGS. 1A and 1B.

FIG. 3C is a sketch in sectional view showing a stitched wire off-die terminal, formed as shown in FIGS. 3A and 3B.

FIGS. 4A, 4B are diagrammatic sketches in sectional view showing formation of a stitched wire off-die terminal using a bonding wedge according to an embodiment.

FIG. 4C is a sketch in sectional view showing a stitched wire off-die terminal, formed as shown in FIGS. 4A and 4B according to an embodiment.

FIG. 5A is a diagrammatic sketch in sectional view showing formation of a stitched wire off-die terminal using a bonding wedge according to another embodiment.

FIG. 5B is a diagrammatic sketch in sectional view showing a stitched wire off-die terminal, formed as shown in FIG. 5A according to an embodiment.

FIGS. 6A and 6B are diagrammatic sketches in sectional view showing a bonding wedge according to an embodiment. The sectional view of FIG. 6A is taken as shown at A-A in FIG. 6B, and the sectional view of FIG. 6B is taken as shown at B-B in FIG. 6A.

### DETAILED DESCRIPTION

The invention will now be described in further detail by reference to the drawings, which illustrate alternative embodiments. The drawings are diagrammatic, showing features of the invention and their relation to other features and structures, and are not made to scale. For improved clarity of presentation, in the Figs. illustrating embodiments, elements corresponding to elements shown in other drawings are not all particularly renumbered, although they are all readily identifiable in all the Figs. Also for clarity of presentation certain features are not shown in the Figs., where not necessary for an understanding of the invention.

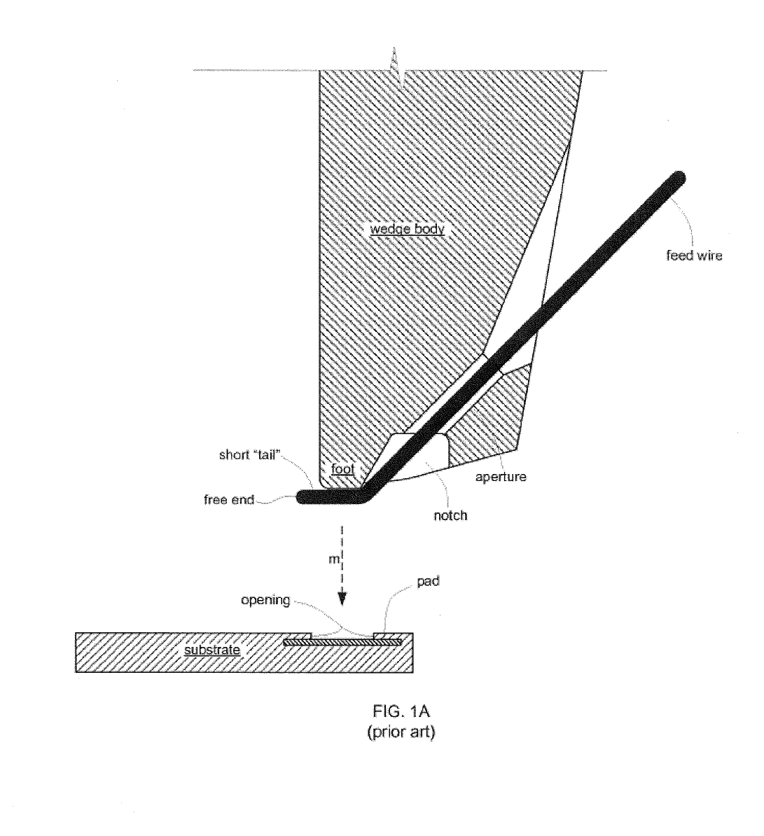

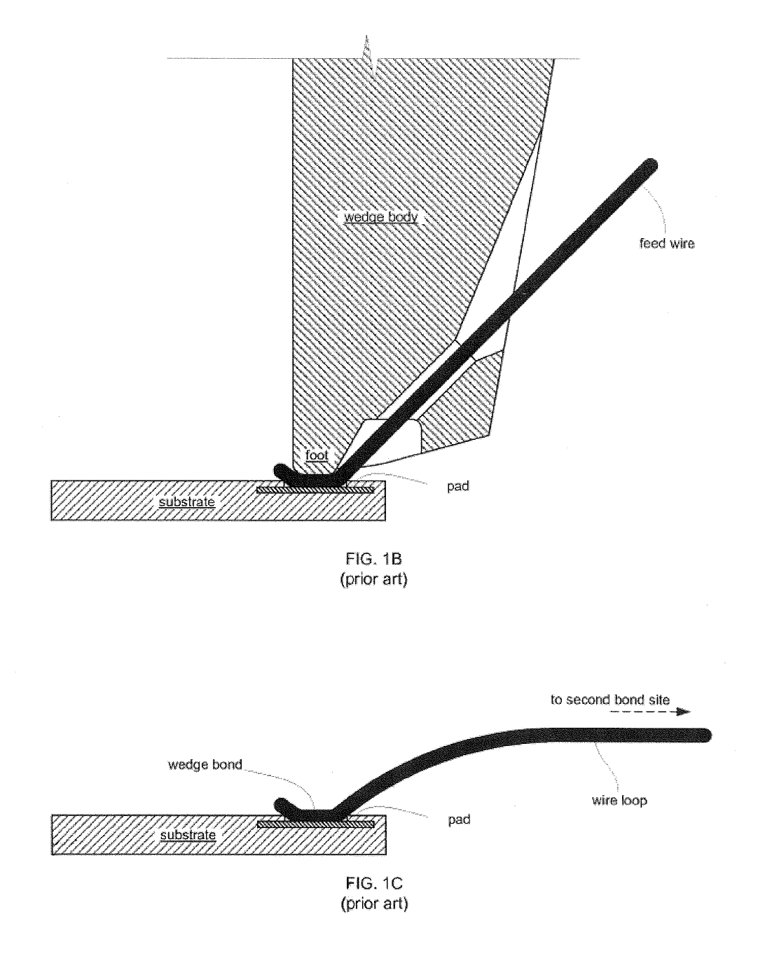

Turning now to FIGS. 1A and 1B, a bonding wedge known in the art includes a wedge body. At the tip of the wedge body is a foot. An inclined aperture opens to a notch or pocket adjacent the back of the foot. A conductive wire is supplied from a spool and fed through the aperture and under the foot. In the example shown a tail of the wire extends a very short distance beyond the front of the foot. In other examples the free end of the wire may end more nearly at the front of the foot.

A first bond site as shown in FIGS. 1A, 1B and 1C includes a bond pad connected to circuitry (not shown) in a substrate. An opening in a passivation layer exposes an area of the pad at the bond site. Any of a variety of bond sites may constitute the first bond site; particularly, for example, the first bond site may be an interconnect pad on a semiconductor die.

To form a stitch bond on a connection site, the bonding tool is moved toward the site, as indicated by the broken arrow m in FIG. 1A. When the wire contacts the site, force is applied to press the wire against the site, and heat and ultrasound energy are applied to complete the bond, as shown in FIG. 1B. Then wire is fed through the bonding tool as the tool is raised and moved laterally away from the completed bond, following a predetermined path toward a second bond site, forming a wire loop, as shown in FIG. 1C.

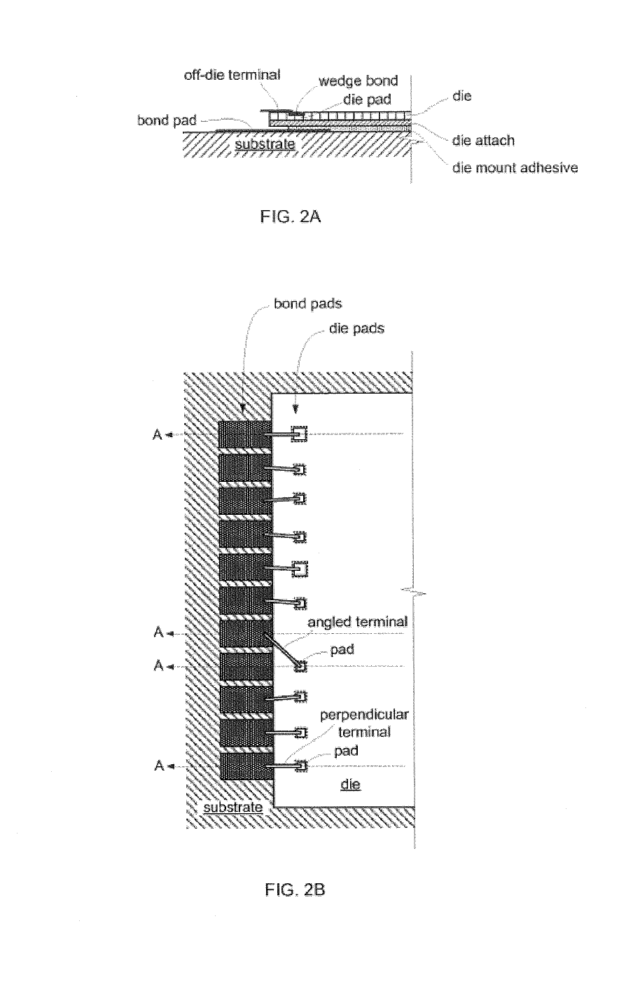

FIGS. 2A and 2B show a die mounted onto a support. The die is provided with stitched wire off-die terminals. In this instance the support is shown as a package substrate. Any of a variety of structures may constitute the support; in other examples the support may be another die, or a printed circuit board, for example. In this example the die is backed by a die attach film, and is mounted onto a die mount surface of the substrate using a die mount adhesive. The die is oriented on the substrate such that the interconnect edge of the die overlies a row of bond pads, and is aligned such that the die pads are generally vertically aligned with the bond pads in the row on the substrate. Openings through a passivation at the front side of the die expose areas of the die pads at the bond sites. The broken arrows A show the centerlines of some of the bond pads on the substrate. Some of the die pads are well-aligned with the underlying bond pads, while others are slightly out of alignment. Where the die pads and the underlying bond pads are well-aligned, the off-die terminal wires are oriented perpendicularly to the interconnect die edge over which they extend. Where a die pad is slightly misaligned with the underlying bond pad, the off-die terminal wire are oriented as a suitable small angle off perpendicular to the interconnect die edge. In one instance in this example, a die pad is intended to be electrically interconnected not to the bond pad over which it is aligned, but rather to an adjacent bond pad; and in this instance the off-die terminal wire is angled so that the free end of the wire overlies the intended bond pad.

Interconnection of a die as in FIGS. 2A and 2B to one or more other die, or connection of a die to circuitry in an underlying support such as a substrate or printed circuit board, is made by way of vertical traces of interconnect material into which the off-die terminals project. There the connection is to circuitry on a support, the interconnect trace has a foot portion that contacts the surface of the bond pad in the support; and a vertical portion into which the off-die terminal projects

As noted, two or more die in a stack may be interconnected in this manner. The interconnect sidewalls and interconnect edges, as well as the front sides of the die are coated before stacking with an electrically insulative film, to prevent unwanted electrical contact in the assembly. Openings are made through the electrically insulative coating at the die pads to permit contact of the off-die terminals.

In particular examples, the interconnect traces or lines are formed of a conductive material that is applied in flowable form, and then cured or allowed to cure to complete the electrically conductive traces or lines. The material may or may not be electrically conductive to at least some extent in flowable form. Where the material as applied prior to cure is nonconductive, or is conductive to an insufficient extent, the cure renders the material sufficiently electrically conductive or the material may be.

Such materials include, for example, electrically conductive polymers, including electrically conductive particulates (e.g., conductive metal particles) contained in a curable organic polymer matrix (for example, conductive (e.g., filled) epoxies, or electrically conductive inks); and include, for example, electrically conductive particulates delivered in a liquid carrier. In particular embodiments the interconnect material is a conductive polymer such as a curable conductive polymer, or a conductive ink. For some materials, as may be understood, the cure may include a sintering process.

In some examples the conductive material includes electrically conductive particles in a curable polymer matrix, such as a curable epoxy. In particular such examples, the conductive material includes particles of Bismuth, Copper, and Tin, in an epoxy matrix; in other such examples the conductive material includes particles of Bismuth, Copper, Tin, and Silver in an epoxy matrix.

Particular examples of suitable interconnect materials include electrically conductive pastes that include an organic polymer with various proportions of particles of Cu, Bi and Sn, or Cu, Bi, Sn and Ag. During cure, these materials can form intermetallics in the trace itself (particularly, for example, CuSn intermetallics) during cure; and where the surface of a bond pad or interconnect terminal or connection site is provided with gold, for example, these materials can form AuSn intermetallics at the interface of the trace and the surface of the pad or site.

Other particular examples of suitable interconnect materials include silver-filled epoxies.

The interconnect material can be applied using an application tool such as, for example, a syringe or a nozzle or a needle. The material exits the tool in a deposition direction generally toward the die pad or interconnect terminal or bond site, and the tool is moved over the presented stack face in a work direction to form a trace or line. The material may be extruded from the tool in a continuous flow; or, the extrusion of the material may be pulsed; or, the flow may be interrupted by valving; or, the material may exit the tool dropwise. In some embodiments the material exits the tool as a jet of droplets, and is deposited as dots which coalesce upon contact, or following contact, with a stack face surface. Various modes of pulse dispense are described in T. Caskey et al. U.S. patent application Ser. No. 12/124,097, titled “Electrical interconnect formed by pulsed dispense”, which was filed May 20, 2008, and which is hereby incorporated by reference herein.

In some examples the traces are formed one at a time. In some examples more than one interconnect trace is formed in a single interconnect operation, and in some such examples all the interconnect traces on a given assembly are formed in a single operation (or in a number of operations fewer than the number of traces). The application tool may in such instances include a number of needles or nozzles ganged together in a row generally parallel to the die edges.

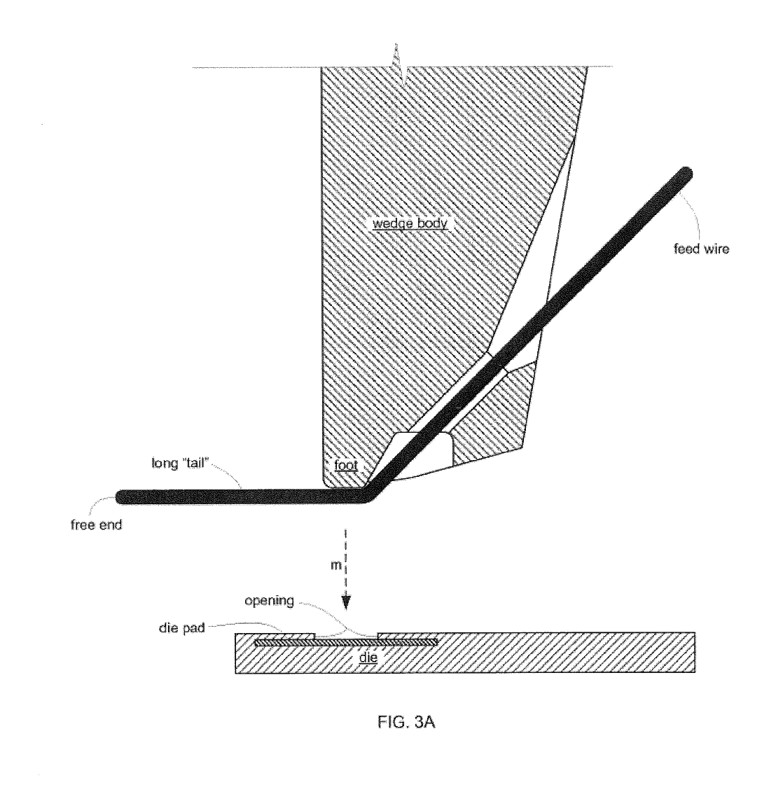

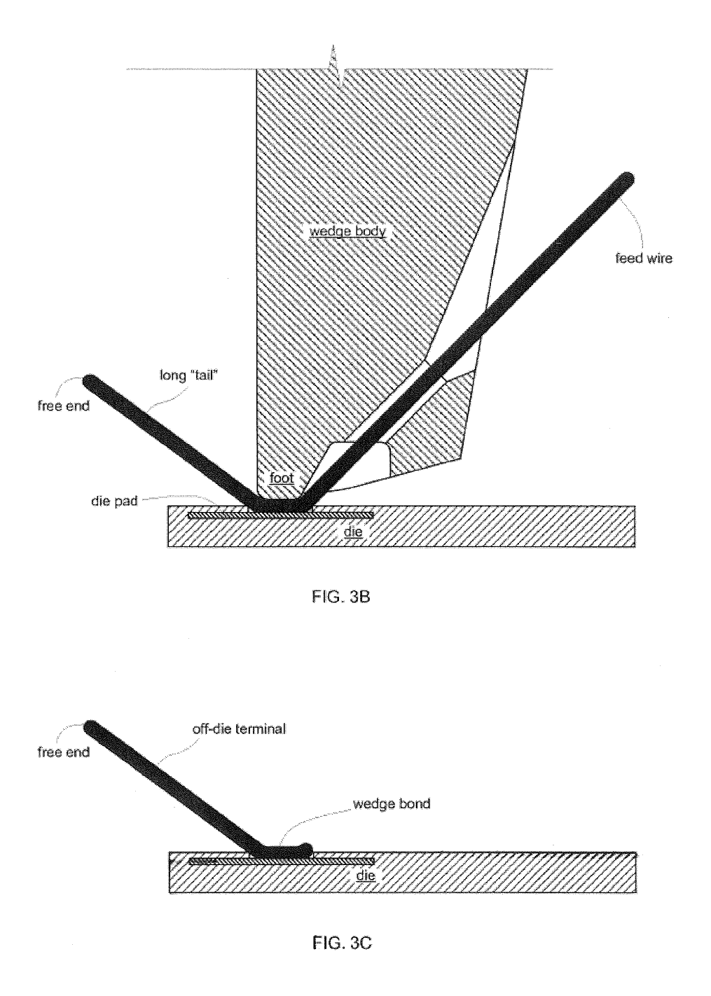

As noted above, we have observed that, in forming stitched wire off-die interconnects using known wedge bonding tools such as is shown for example in FIG. 1A, the stitch bonding process results in extended wires angled sharply upward, that is, well above the plane of the active side of the die. This undesirable result is illustrated in FIGS. 3A, 3B and 3C. FIG. 3A shows a wedge bonding tool of a known design, as in FIG. 1A, poised to form a stitched wire off-die interconnect: the wire has been fed through the aperture and the notch or pocket and under the foot; and a long tail of the wire extends the free wire end well beyond the front of the foot.

To form a stitch wire off-die terminal at a site on a die pad, the bonding tool is moved toward the site, as indicated by the broken arrow m in FIG. 3A. When the wire contacts the site, force is applied to press the wire against the site, and heat and ultrasound energy are applied to complete the bond, as shown in FIG. 3B. Then wire is fed through the tool as the tool is raised and moved away from the bond, and when a suitable length of wire has been drawn through, the wire is snapped off near the completed wedge bond, form a new free wire end on a long tail. The completed stitch wire off-die terminal is shown in FIG. 3C. The tool can then be moved to another die pad and the process repeated to form an off-die terminal there.

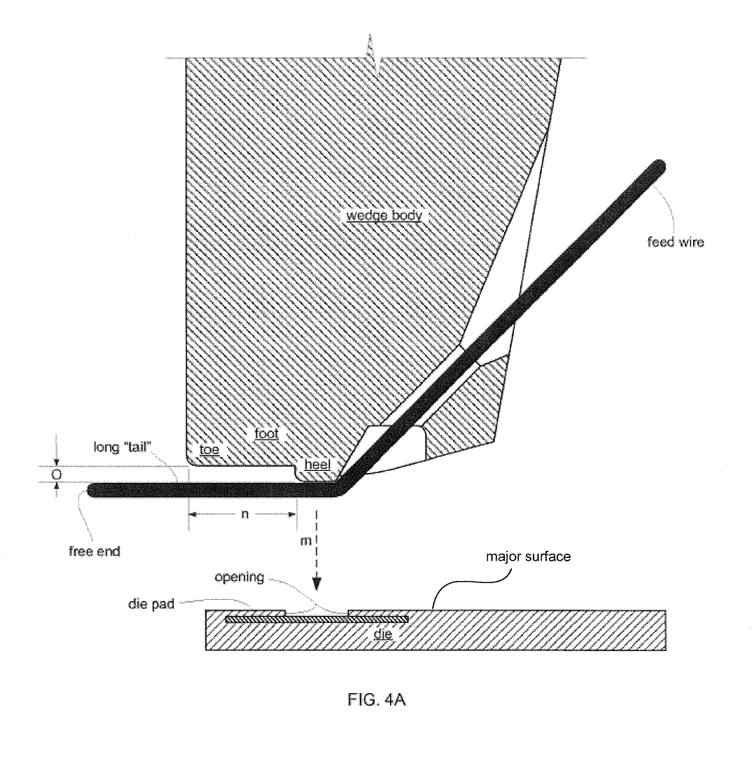

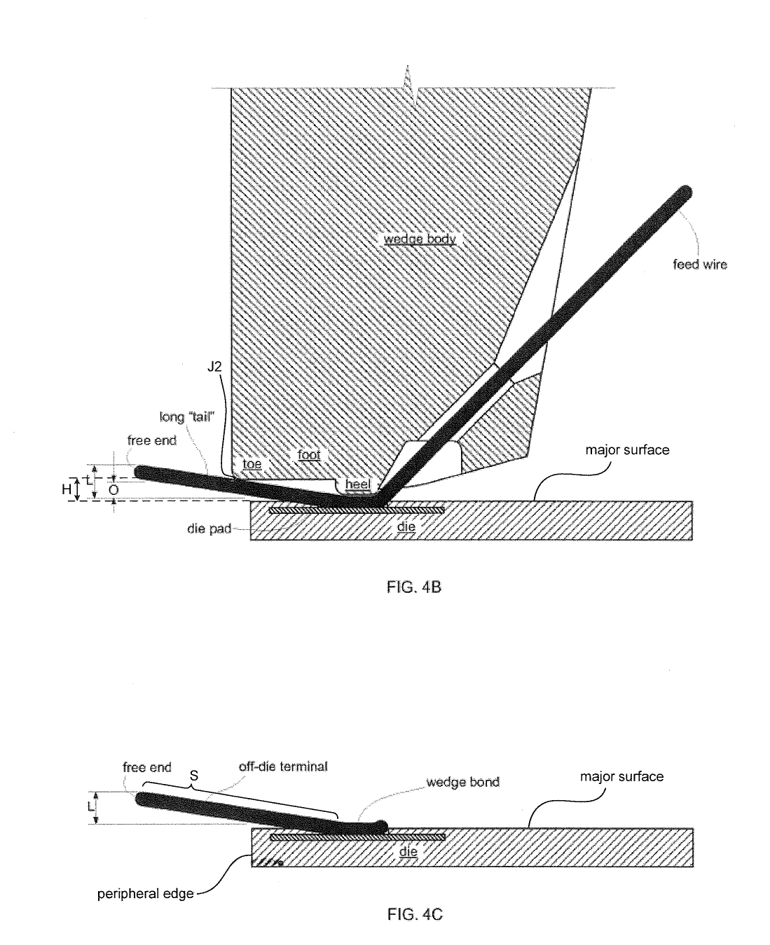

As FIGS. 3B and 3C illustrate, the long lead of the off-die terminal resulting from this procedure is angled sharply upward, well above the plane of the active side of the die. This undesirable condition is avoided or substantially reduced according to the invention, as shown in FIGS. 4A, 4B and 4C.

Turning now to FIGS. 4A and 4B, a bonding wedge according to an embodiment of the invention includes a wedge body. At the tip of the wedge body is a foot, which includes a heel portion and a toe portion. In one example, underside of the front of the toe can be offset, i.e., displaced in a direction upward from the underside of the heel by a dimension O, and the front side of the heel can be set back, i.e., displaced in a lateral direction (horizontally) from the front side of the toe by a dimension n. The dimension n in one example may be greater than twice a diameter of the wire. In one example, as shown in FIG. 4B, the toe may have a flat surface extending in the lateral direction between the front side of the heel and the front side of the toe and such flat surface may contact the free end of the wire during the bonding operation. An inclined aperture opens to a notch or pocket adjacent the back of the heel. A conductive wire is supplied from a spool and fed through the aperture and under the foot. The free end of the wire extends well beyond the front side of the toe. The dimension O may be at least as great as a diameter of the wire at an outer surface of the wire. In one example as seen in FIGS. 4A-4C, the dimension O may be a distance equal to or greater than a sum of the diameter of the wire at an outer surface of the wire and a distance in the upward direction from the exposed contact pad to the major surface of the component. In such way, the underside of the toe at the front side thereof can be displaced upwardly from the underside of the heel at the front side of the heel by a distance of at least the diameter of the wire (at the outer surface thereof) and a distance in the upward direction from the exposed contact pad to the major surface of the component.

FIG. 4A shows the wedge bonding tool according to an embodiment of the invention, poised to form a stitched wire off-die interconnect: a wire supplied from a spool has been fed through the aperture and the notch or pocket and under the foot; and a long tail of the wire extends the free wire end well beyond the front of the toe. The wedge bonding tool is seen positioned above a contact pad which is exposed at a major surface of a component. The contact pad may be a die pad of a semiconductor die, and a dielectric layer, e.g., passivation layer, may have a surface which defines the major surface of the component. For example, a portion of the contact pad may be exposed within an opening in the dielectric layer. As used herein, a statement that an electrically conductive element is “exposed at” a surface of a structure indicates that the electrically conductive element is available for contact with a theoretical point moving in a direction perpendicular to the surface toward the surface from outside the structure. Thus, a terminal or other conductive element which is exposed at a surface of a structure can project from such surface; can be flush with such surface; or can be recessed relative to such surface and exposed through a hole or depression in the structure.

To form a stitch wire off-die terminal at a site on a contact pad exposed at a major surface of a component die pad, the bonding tool is moved toward the site, as indicated by the broken arrow m in FIG. 4A. When the wire contacts the site, force is applied to press the wire against the site, and heat and ultrasound energy are applied to complete the bond, as shown in FIG. 4B. Then wire is fed through the tool as the tool is raised and moved away from the bond, and when a suitable length of wire has been drawn through, the wire is severed, e.g., snapped off by the wedge body near the completed wedge bond, to form a new free wire end on a long tail. The completed stitch wire off-die terminal is shown in FIG. 4C. As illustrated, the free end of the wire may be disposed beyond a peripheral edge of the component, such edge extending away from the component major surface. The tool can then be moved to another die pad and the process repeated to form an off-die terminal there.

As FIGS. 4B and 4C illustrate, contact of the long tail with the toe during the bonding process mitigates the upward displacement of the free end of the wire. In particular, the free end of the off-die terminal wire in FIG. 4C is kept within a dimension L above the plane of the active side of the die. However, the exact dimension of L is a function of the length of the tail of the wire from the first location to the free end of the wire. As further seen in FIG. 4B, when the heel contacts a first location of the wire to bond the wire to the contact pad, the toe may simultaneously contact a location J2 of the wire, which can set a height H of the wire above the component major surface at the second location J2.

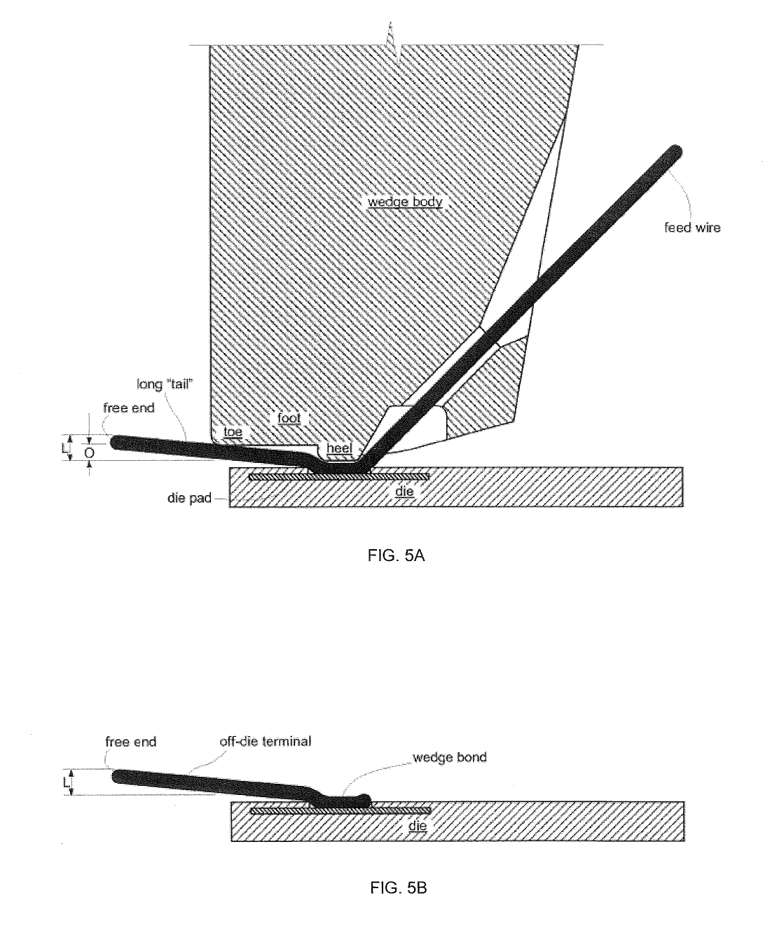

FIGS. 4A, 4B show the appearance in an example where the passivation layer adjacent the opening over the die pad is soft enough to be deformed by the force of the wire during the bonding process. FIG. 5A illustrates a stage of fabrication of an off-die terminal during the bonding process, in an example where the passivation layer adjacent the opening over the die pad constitutes a firmer material than that shown in FIGS. 4A, 4B. In the example seen in FIGS. 5A and 5B the passivation layer adjacent the opening resists deformation by the wire and, consequently, the wire is bent at that point during the bonding process. As the sketches suggest, this may result in even more improved mitigation of the upward displacement of the free end of the wire (a smaller dimension L).

The dimension L will differ according to the length of the long tail and the diameter of the wire as well as according to the dimensions O and n of the underside of the foot, and the dimensions of the foot can be selected to achieve a desired dimension L. In one example, where the dimension n is 0.135 mm and the dimension O is 0.025 mm, the extension of the tail beyond the front of the heel may be about 0.235 mm, and the wire diameter can be 0.018 mm in one example, and the elevation L of the free end can be about 0.050 mm or less. It can also be seen that the elevation L of the free end in a direction perpendicular to a plane defined by the major surface, and the length S of the tail of the wire between the free end and the first location of the wire defines an angle between the tail and the major surface which angle is less than 45 degrees. The length of the tail can define the hypotenuse of a right triangle of which L is the elevation, in which case L is equal to S multiplied by the sine of such angle, i.e., the angle between the tail of the wire and the component major surface. In one example, the angle can be less than 30 degrees. In another example, the measure of the angle may be even substantially less than 30 degrees.

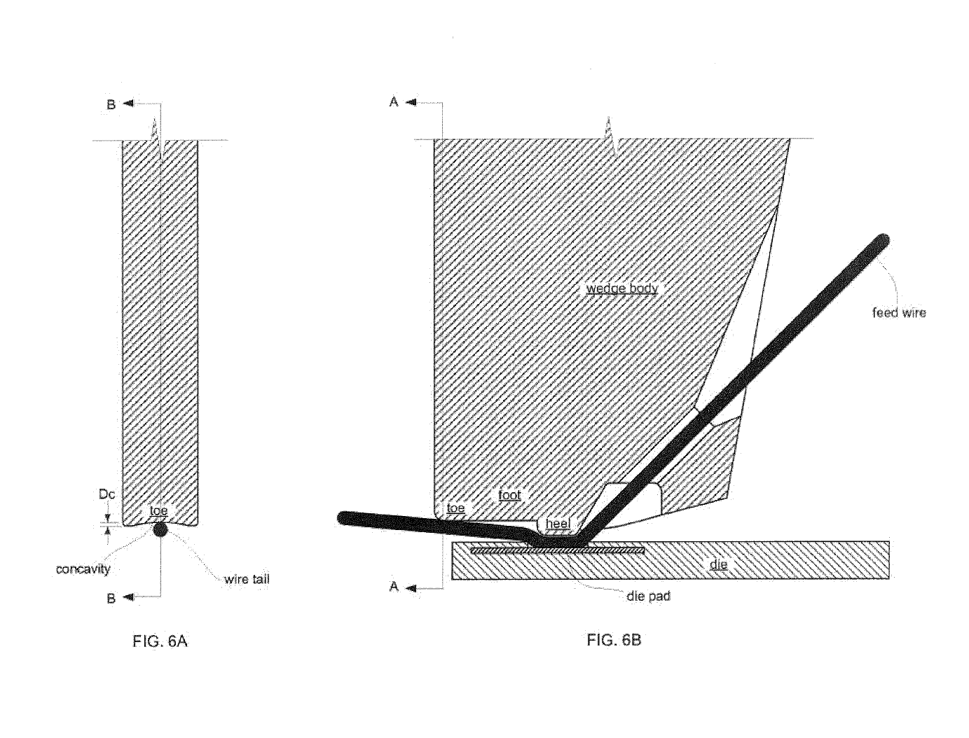

In some examples the wedge tip may be further refined by forming an upward-concavity at the lower surface of the toe, where the toe contacts the wire during the bonding process. An example appears in FIG. 6A, showing a sectional view across the tip of the toe as indicated at A-A in FIG. 6B. The concavity helps to guide the tail of the wire during the bonding process and can help maintain alignment of the wire tail beneath the toe during the bonding process, to ensure that the long lead has the desired angle with respect to the die edge. The concavity may have a generally curved cross-section, as shown in this example; or it may have the form of a channel extending in the lateral direction from the front side of the toe towards the heel or in form of an angled trough. The greatest depth Dc of the trough or curve may be at the center of the cross section of the toe, so that the wire is kept aligned with the midline of the wedge foot during the bonding process. The depth of the concavity may be less than the diameter of the specified wire, and usually is less than half the wire diameter.

For stability it may be preferable to form the toe as an integral part of the wedge tip. In some embodiments the toe portion of the wedge constitutes an attachment accessory to a bonding wedge that has a foot with a heel but lacks a toe. In this manner an off-the-shelf wedge may be retrofitted for use in a particular application.

As will be appreciated, a die having stitched wire off-die interconnects formed as described above can be mounted onto, and electrically connected to circuitry in, an underlying support. Alternatively, a stack of die having stitched wire off-die interconnects formed as described above can be mounted onto, and electrically connected to circuitry in, an underlying support.

Various features of the above-described embodiments of the invention can be combined in ways other than as specifically described above without departing from the scope or spirit of the invention. It is intended for the present disclosure to cover all such combinations and variations of embodiments of the invention described above.

1. A wedge-bonding tool, comprising:
a wedge body having a foot configured to apply a downward force on a wire during the bonding of the wire to a contact pad of a component exposed at a major surface of the component, the foot including a toe and a heel, a front side of the toe being displaced from a front side of the heel in a lateral direction parallel to the major surface and an underside of the toe displaced from an underside of the heel in an upward direction away from the major surface, the heel being configured to apply the force at a first location of the wire proximate the contact pad to bond the wire to the contact pad, and the toe being configured to simultaneously contact a tail of the wire at a second location of the wire in a state in which the heel is applying the force so as to set a height of the wire above the component major surface at the second location.

2. The wedge-bonding tool of claim 1, wherein the toe has a lower surface having a concavity therein which is configured to guide the tail of the wire.

3. The wedge-bonding tool of claim 1, wherein the depth of the concavity is less than a diameter of the wire defined by an outer surface of the wire.

4. The wedge-bonding tool of claim 1, wherein the component is a semiconductor die, and in a state in which the wire has been bonded to the contact pad, the wedge body is configured such to affect a tail of the wire having a free end to have an elevation L in a direction perpendicular to a plane defined by the major surface, such that the a length S of the tail of the wire between the free end and the first location of the wire defines an angle between the tail and the major surface, the angle being less than 45 degrees.

5. The wedge-bonding tool of claim 4, wherein the angle is less than 30 degrees.

6. The wedge-bonding tool of claim 4, wherein the component has a peripheral edge extending away from the major surface and the wedge-bonding tool is configured to leave the free end of the wire disposed beyond the peripheral edge.

7. The wedge-bonding tool of claim 1, wherein the wedge body is configured to sever the wire at a location proximate the contact pad.

8. The wedge-bonding tool of claim 1, wherein the toe has a flat surface extending in the lateral direction between the front side of the heel and the front side of the toe.

9. The wedge-bonding tool of claim 1, wherein the underside of the toe at the front side thereof is displaced upwardly from the underside of the heel at the front side of the heel by a distance of at least a diameter of the wire at an outer surface thereof.

10. The wedge-bonding tool of claim 9, wherein the contact pads are exposed within at least one opening in a dielectric layer having a surface defining the major surface of the component, wherein the underside of the toe at the front side thereof is displaced upwardly from the underside of the heel at the front side of the heel by a distance of at least a diameter of the wire at an outer surface thereof and a distance in the upward direction from the exposed contact pad to the major surface of the component.

11. The wedge-bonding tool of claim 1, wherein the front side of the toe is displaced in the lateral direction from the front side of the heel by a distance greater than twice the diameter of the wire.

12. A wedge-bonding method, comprising:
positioning a wedge body having a wire extending therefrom proximate a contact pad of a component having a major surface, and moving the wedge body downwardly such that a heel of the wedge body applies a force on the wire at a first location of the wire proximate the contact pad to bond the wire to the contact pad, and such that an underside of a toe of the wedge body which is laterally and upwardly displaced from the heel contacts a tail of the wire at a second location of the wire at a time when the heel applies the force so as to set a height of the wire above the component major surface at the second location.

13. The wedge-bonding method of claim 12, wherein the toe has a lower surface having a concavity therein, wherein the concavity guides the tail of the wire.

14. The wedge-bonding method of claim 12, wherein the depth of the concavity is less than a diameter of the wire defined by an outer surface of the wire.

15. The wedge-bonding method of claim 12, wherein the component is a semiconductor die, and the tail of the wire has a free end, and the moving is performed such that an elevation L of the free end in a direction perpendicular to a plane defined by the major surface, and a length S of the wire between the free end and the first location of the wire defines an angle between the tail of the wire and the major surface, the angle being less than 45 degrees.

16. The wedge-bonding method of claim 15, wherein the angle is less than 30 degrees.

17. The wedge-bonding method of claim 16, wherein the component has a peripheral edge extending away from the major surface and the moving is performed so as to form the wire having the free end extending beyond the peripheral edge.

18. The wedge-bonding method of claim 12, further comprising severing the wire at a location proximate the contact pad.

19. The wedge-bonding method of claim 12, wherein the toe has a flat surface extending in the lateral direction between the front side of the heel and the front side of the toe, the method further comprising contacting the wire with at least a portion of the flat surface.

20. The wedge-bonding method of claim 12, wherein the underside of the toe at the front side thereof is displaced upwardly from the underside of the heel at the front side of the heel by a distance of at least a diameter of an outer surface of the wire.

21. The wedge-bonding method of claim 20, wherein the contact pads are exposed within at least one opening in a dielectric layer having a surface defining the major surface of the component, wherein the underside of the toe at the front side thereof is displaced upwardly from the underside of the heel at the front side of the heel by a distance of at least a diameter of an outer surface of the wire and a distance in the upward direction from the exposed contact pad to the major surface of the component.

22. The wedge-bonding method of claim 12, wherein the front side of the toe is displaced in the lateral direction from the front side of the heel by a distance greater than twice the diameter of the wire.
